(19) United States
(12) Patent Application Publication
(10) Pub. No.: US 2025/0164888 A1
(43) Pub. Date: May 22, 2025

(54) PHOTORESIST REMOVER COMPOSITION

(71) Applicant: KANTO KAGAKU KABUSHIKI KAISHA, Tokyo (JP)

(72) Inventors: Tsubasa ITO, Saitama (JP); Ryo SASAKI, Saitama (JP); Toshikazu SHIMIZU, Saitama (JP)

(21) Appl. No.: 18/728,974

(22) PCT Filed: Jan. 20, 2023
(86) PCT No.: PCT/JP2023/001639

§ 371 Date: Jul. 15, 2024

(30) Foreign Application Priority Data
Jan. 21, 2022 (JP) 2022-008168

(51) Int. Cl. G03F 7/42

(52) U.S. Cl. CPC G03F 7/425

(57) ABSTRACT

An object of the present invention is to provide a photoresist stripping composition which exhibits high stripping performance even for a cured resist, prevents corrosion of substrate-forming metals, such as Cu and Al, that come in contact with a liquid, and can prevent excessive oxidation of a metal such as Cu during a stripping process. The object was achieved by a photoresist stripping composition, the composition containing a quaternary ammonium hydroxide (A), diethylene glycol monoethyl ether (B), glycerin (C), and water (D), wherein a content of (A) is 0.5 to 5 mass % with respect to a total mass of the composition, a content of (B) is 50 to 95 mass % with respect to the total mass of the composition, a content of (C) is 0.5 to 20 mass % with respect to the total mass of the composition, and a content of (D) is less than 20 mass % with respect to the total mass of the composition.

### TECHNICAL FIELD

The present invention relates to a photoresist stripping composition.

### BACKGROUND ART

The photoresist stripping composition is used for stripping an unnecessary photoresist film after an etching or plating process in photolithography for forming a metal wiring pattern of Cu or the like on a silicon substrate or a glass substrate. In the etching or plating process, since a resist polymer is cured by crosslinking, a stripper capable of stripping a cured resist is required.

In addition, Cu and Al are often used as metals used for wiring, and a stripper having excellent anticorrosive property for Cu and Al is desired. Therefore, in order to improve the anticorrosive property for Al, a composition to which an Al anticorrosive agent is added has been developed, but there has been a problem that the addition of the Al anticorrosive agent may deteriorate stripping performance.

Therefore, there has been a demand for a stripper having anticorrosive property for Cu and Al and stripping performance.

Meanwhile, a method of applying an ultrasonic wave for stripping a cured photoresist has been used. By applying an ultrasonic wave, due to the cavitation effect, a stripping liquid enters between a base film and a resist, and the resist is pulverized and stripped by a shock wave. The use of a stripping liquid containing N-methylpyrrolidinone (NMP) effective for the method is limited from the viewpoint of environmental load and toxicity to human body, and there are problems such as low resist dissolution performance, an increase in the number of liquid exchanges, and a concern about re-adhesion to the resist substrate.

Patent Literature 1 discloses a photoresist stripping liquid containing tetramethylammonium hydroxide (TMAH), diethylene glycol monoethyl ether (EDG), sorbitol, alkanolamine, and water.

Patent Literature 2 discloses a treatment liquid for a semiconductor device containing a hydroxylamine compound, an organic basic compound, an alcohol-based solvent, a surfactant, and the like.

Patent Literature 3 discloses a composition containing TMAH, an alcohol solvent, an Al corrosion preventive agent, and water, and describes that the composition strips a thick-film positive or negative resist.

Patent Literature 4 discloses a composition containing TMAH, glycerin, EDG, and carboxybenzotriazole, and describes that the composition strips a positive photoresist and a negative photoresist.

Patent Literature 5 discloses a composition containing TMAH, EDG, and water, and describes that the composition can effectively remove a residual substance of a photoresist film and an etching residue on a substrate on which at least a metal layer containing tantalum is formed as a conductive metal film.

### CITATION LIST

### Patent Literature

### Patent Literature 1: WO 2021/020410 A

### Patent Literature 2: WO 2019/187868 A

### Patent Literature 3: JP 2018-503127 A

### Patent Literature 4: JP 2013-527992 A

Patent Literature 5: JP 2008-58625 A

### SUMMARY OF INVENTION

### Technical Problem

However, the conventional photoresist strippers have problems that the stripping performance is insufficient for an excessively cured photoresist, or corrosion prevention of Cu or Al is insufficient. In view of the above conventional problems, an object of the present invention is to provide a photoresist stripping composition which exhibits high stripping performance even for a cured resist, prevents corrosion of substrate-forming metals, such as Cu and Al, that come in contact with a liquid, and can prevent excessive oxidation of a metal such as Cu during a stripping process.

### Solution to Problem

The present inventors have conducted studies to solve the above problems, and found that a photoresist stripping composition, the composition containing a quaternary ammonium hydroxide (A), diethylene glycol monoethyl ether (B), glycerin (C), and water (D), wherein a content of (A) is 0.5 to 5 mass % with respect to a total mass of the composition, a content of (B) is 50 to 95 mass % with respect to the total mass of the composition, a content of (C) is 0.5 to 20 mass % with respect to the total mass of the composition, and a content of (D) is less than 20 mass % with respect to the total mass of the composition, exhibits high stripping performance even for a cured resist, prevents corrosion of metals such as Cu and Al, and can prevent excessive metal oxidation during a stripping process, and thus completed the present invention.

That is, the present invention relates to the following.

[1] A photoresist stripping composition, the composition containing a quaternary ammonium hydroxide (A), diethylene glycol monoethyl ether (B), glycerin (C), and water (D), wherein a content of (A) is 0.5 to 5 mass % with respect to a total mass of the composition, a content of (B) is 50 to 95 mass % with respect to the total mass of the composition, a content of (C) is 0.5 to 20 mass % with respect to the total mass of the composition, and a content of (D) is less than 20 mass % with respect to the total mass of the composition.

[2] The composition according to [1], wherein the composition does not contain hydroxylamine or a hydroxylamine salt.

[3] The composition according to [1] or [2], wherein the content of water (D) is 5 mass % or less with respect to the total mass of the composition.

[4] The composition according to any one of [1] to [3], wherein the composition further contains ethylene glycol (E), a content of which is 1 to 10 mass % with respect to the total mass of the composition.

[5] The composition according to any one of [1] to [4], wherein the composition further contains an alkanolamine (F), a content of which is 1 to 20 mass % with respect to the total mass of the composition.

[6] The composition according to [5], wherein the alkanolamine (F) is monoethanolamine, diethanolamine, or 2-(2-aminoethoxy) ethanol.

[7] The composition according to any one of [1] to [6], wherein the composition further contains (G) at least one selected from a group consisting of 4-carboxybenzotriazole and 5-carboxybenzotriazole, wherein a total content of (G) is 0.05 to 1.00 mass % with respect to the total mass of the composition.

[8] The composition according to any one of [1] to [7], wherein the quaternary ammonium hydroxide (A) is one or more selected from a group consisting of tetramethylammonium hydroxide, tetraethylammonium hydroxide, choline hydroxide, and ethyltrimethylammonium hydroxide.

[9] The composition according to any one of [1] to [8], wherein the composition does not contain dimethyl sulfoxide or N-methylpyrrolidone.

[10] The composition according to any one of [1] to [9], wherein the composition does not contain sodium hydroxide or potassium hydroxide.

[11] The composition according to any one of [1] to [10], wherein the composition does not contain a triazine compound.

[12] A photoresist stripping method, including bringing a photoresist applied onto a substrate having metal wiring or a semiconductor substrate containing a photoresist residue into contact with the composition according to any one of [1] to [11] remove the photoresist.

### Advantageous Effects of Invention

The photoresist stripping composition of the present invention exhibits high stripping performance even for a cured resist, prevents corrosion of metals such as Cu and Al, and can prevent excessive oxidation of a metal during a stripping process. Excessive oxidation of a metal causes device defects. In particular, under ultrasonic application conditions, excessive metal oxidation is likely to occur such that water is thermally decomposed at a hot spot generated by ultrasonic application, hydroxy radicals are generated, and thus a metal is oxidized. The photoresist stripping composition of the present invention can prevent corrosion and excessive oxidation of Cu, Al, and the like even under such ultrasonic application conditions.

The composition of the present invention does not require a highly toxic solvent.

### DESCRIPTION OF EMBODIMENTS

Hereinafter, the present invention will be described in detail based on preferred embodiments of the present invention.

The photoresist stripping composition of the present invention is
a photoresist stripping composition, and
the composition is a composition containing a quaternary ammonium hydroxide (A), diethylene glycol monoethyl ether (B), glycerin (C), and water (D), wherein
a content of (A) is 0.5 to 5 mass % with respect to a total mass of the composition, a content of (B) is 50 to 95 mass % with respect to the total mass of the composition, a content of (C) is 0.5 to 20 mass % with respect to the total mass of the composition, and a content of (D) is less than 20 mass % with respect to the total mass of the composition. The photoresist stripping composition exhibits high stripping performance even for a cured resist, prevents corrosion of metals such as Cu and Al, and can prevent excessive oxidation of a metal such as Cu during a stripping process.

In the present description, the numerical range “a to b” means “a or more and b or less”.

Hereinafter, each component contained in the composition of the present invention will be described.

The composition of the present invention contains quaternary ammonium hydroxide (A).

Examples of the quaternary ammonium hydroxide include tetramethylammonium hydroxide, tetraethylammonium hydroxide, tetrapropylammonium hydroxide, tetrabutylammonium hydroxide, benzyltriethylammonium hydroxide, benzyltrimethylammonium hydroxide, ethyltrimethylammonium hydroxide, choline hydroxide, dimethyl bis(2-hydroxyethyl) ammonium hydroxide, and monomethyl tris(2-hydroxyethyl) ammonium hydroxide. The quaternary ammonium hydroxide is preferably one or more selected from the group consisting of tetramethylammonium hydroxide, tetraethylammonium hydroxide, choline hydroxide, and ethyltrimethylammonium hydroxide from the viewpoint of purity, solubility in a solvent, and the like.

The content of the quaternary ammonium hydroxide is 0.5 to 5 mass % with respect to the total mass of the composition. The content of the quaternary ammonium hydroxide is preferably 0.5 to 3 mass % with respect to the total mass of the composition.

The composition of the present invention contains diethylene glycol monoethyl ether (EDG) (B).

The content of diethylene glycol monoethyl ether is 50 to 95 mass % with respect to the total mass of the composition. In an aspect, the content of diethylene glycol monoethyl ether is preferably 60 to 95 mass %, 65 to 95 mass %, 70 to 95 mass %, 75 to 95 mass %, 80 to 95 mass %, 85 to 95 mass %, or 90 to 95 mass % with respect to the total mass of the composition from the viewpoint of resist stripping performance and resist dissolution performance, prevention of metal corrosiveness, and the like.

The composition of the present invention contains glycerin (C). Surprisingly, incorporation of glycerin improves both anticorrosion of a metal such as Al against a quaternary ammonium salt or the like, and stripping performance. Examples of the Al anticorrosive agent that is often used include sorbitol and xylitol, but these have low solubility in EDG and therefore have a problem that they deposit. Sorbitol, xylitol, and the like also have low solubility in isopropyl alcohol (IPA) used in the subsequent washing, and therefore IPA rinse is not possible. Glycerin has high solubility in EDG and IPA and is preferable.

The content of glycerin (C) is 0.5 to 20 mass % with respect to the total mass of the composition. From the viewpoint of sufficient Al anticorrosion and high stripping performance, the content of glycerin is preferably 1 to 15 mass %, 5 to 15 mass %, or 10 to 15 mass % with respect to the total mass of the composition.

The composition of the present invention contains water (D).

The content of water is less than 20 mass % with respect to the total mass of the composition. From the viewpoint of resist dissolution performance, metal corrosion prevention or the like, the content of water is preferably 0.1 mass % or more and less than 15 mass %, more preferably 0.1 mass % or more and less than 10 mass %, and still more preferably 0.1 mass % or more and 5 mass % or less with respect to the total mass of the composition.

In an aspect, the composition of the present invention does not contain hydroxylamine or a hydroxylamine salt. Hydroxylamine or a hydroxylamine salt is often contained in a conventional stripping composition for removing a residue of Ti metal or Al metal, but metal corrosion occurs and there is a risk of explosion, and therefore, in an aspect, hydroxylamine or a hydroxylamine salt is not contained in the composition of the present invention.

Preferably, the composition of the present invention further contains ethylene glycol (E).

In an aspect, the content of ethylene glycol (E) is 1 to 10 mass % with respect to the total mass of the composition. That is, in an aspect, the stripper of the present invention relates to a composition further containing ethylene glycol (E), the content of which is 1 to 10 mass % with respect to the total mass of the composition.

In an aspect, the composition of the present invention further contains an alkanolamine (F).

The alkanolamine (F) is, for example, monoethanolamine, diethanolamine, triethanolamine, 2-(methylamino) ethanol, 2-(dimethylamino) ethanol, 2-(2-aminoethoxy) ethanol, 2-(2-aminoethylamino) ethanol, 3-amino-1-propanol, 3-(dimethylamino)-1-propanol, 1-amino-2-propanol, or the like, and is preferably monoethanolamine, diethanolamine, or 2-(2-aminoethoxy) ethanol.

In an aspect, the content of the alkanolamine (F) is 1 to 20 mass % with respect to the total mass of the composition. That is, in an aspect, the composition of the present invention further contains an alkanolamine (F), the content of which is 1 to 20 mass %, preferably 5 to 20 mass %, 10 to 20 mass %, or 15 to 20 mass % with respect to the total mass of the composition.

In an aspect, the composition of the present invention further contains an antioxidant. Examples of the antioxidant include benzotriazole (BTA), adenine, 4-carboxybenzotriazole, 5-carboxybenzotriazole, 5-methylbenzotriazole, and 5-amino-1H-tetrazole, and from the viewpoint that there is little residual organic substance derived from the antioxidant after washing, 4-carboxybenzotriazole (4-CBTA) or 5-carboxybenzotriazole (5-CBTA) is particularly preferable. Thus, in an aspect, the composition of the present invention further contains (G) at least one selected from the group consisting of BTA, adenine, 4-carboxybenzotriazole and 5-carboxybenzotriazole, preferably 4-carboxybenzotriazole or 5-carboxybenzotriazole.

In an aspect, the total content of (G) BTA, adenine, 4-carboxybenzotriazole, or 5-carboxybenzotriazole is 0.05 to 1.00 mass % with respect to the total mass of the composition.

In an aspect, the composition of the present invention contains an aprotic polar solvent in an amount of 35% or less, preferably 25% or less, and more preferably 15% or less. Most preferably, the composition of the present invention does not contain an aprotic polar solvent.

Examples of the aprotic polar solvent include dimethyl sulfoxide, N-methylpyrrolidone, sulfolane, and 1, 3-dimethyl-2-imidazolidinone. Preferably, the composition of the present invention does not contain dimethylsulfoxide or N-methylpyrrolidone.

From the viewpoint of preventing device defects due to a remaining metal residue, or the like, it is preferable that the composition of the present invention does not contain sodium hydroxide or potassium hydroxide in an aspect.

In an aspect, the composition of the present invention does not contain a triazine compound. The triazine compound is, for example, 6-phenyl-2, 4-diamino-1,3, 5-triazine, 6-methyl-2,4-diamino-1, 3, 5-triazine, or the like.

The composition of the present invention may contain, for example, a surfactant as an optional component.

As the surfactant, for example, a polyether-modified silicone, a sulfonic acid type surfactant, a phosphate ester type surfactant, a quaternary ammonium type surfactant, a polyoxyethylene alkyl ether, an acetylene-based surfactant, or the like can be used.

The surfactant may be contained, for example, in an amount of 0.05 to 2 mass % with respect to the total mass of the composition.

The photoresist stripping composition of the present invention is a composition for removing a photoresist applied onto a substrate having metal wiring.

In the Cu bumping process, after a photoresist is applied to a substrate, resist patterning is performed by exposure and development, resist openings are filled with Cu plating, and then the resist is stripped to form Cu bumps. The photoresist stripping composition of the present invention can be used when the photoresist is stripped by a wet process in the process.

In addition, in the Cu wiring forming process by etching, after a Cu film is formed on a substrate, a photoresist is applied, resist patterning is performed by exposure and development, and after Cu etching is performed, the photoresist remaining by being layered on the Cu wiring can be stripped by a wet process.

In an aspect, the present invention also relates to a photoresist stripping method including bringing a photoresist or a semiconductor substrate containing a photoresist residue into contact with the composition of the present invention to remove the photoresist or the photoresist residue.

The substrate containing a photoresist refers to, for example, a photoresist applied onto a substrate having metal wiring of Cu and Al or the like formed in the Cu bumping process or the wiring forming process, or the like.

The photoresist residue is a photoresist remaining after a photoresist removal treatment is performed before the photoresist residue is brought into contact with the composition of the present invention. Therefore, examples of the substrate containing a photoresist residue include a substrate on which a resist remains after the resist is roughly removed (ashing) with oxygen plasma.

In some aspects, the photoresist stripping method includes: (A) a step of providing a semiconductor substrate having a photoresist coating; (B) a step of exposing the semiconductor substrate having a photoresist coating to the stripping composition of the present invention to remove the photoresist; (C) a step of rinsing a stripping liquid composition with water or IPA; and (D) a step of drying.

The semiconductor substrate is usually formed of, but not particularly limited to, silicon, silicon oxide, silicon carbide, titanium oxide, aluminum oxide, gallium oxide, gallium nitride, indium phosphide, gallium arsenide, or the like.

Examples of a metal and a metal alloy in a wiring material, a contact material, an electrode material, or the like that forms the substrate include, but are not limited to, copper, aluminum, aluminum alloyed with copper, aluminum alloyed with silicon, titanium, tungsten, cobalt, ruthenium, nickel, chromium, molybdenum, palladium, gold, silver, indium tin oxide, and IGZO.

In some aspects, the stripping composition can be used at about 25 to about 80° C. In some aspects, the stripping composition can be used in a temperature range from about 40° C. to about 80° C. In some aspects, the stripping composition can be used in a temperature range from about 50° C. to about 80° C.

The stripping time can vary depending on the type of the resist, the substrate structure, the stripping device, and the like. When a Cu bump resist is stripped in a batch process, a suitable time range is usually about 5 to 30 minutes.

### EXAMPLES

The present invention will be described together with the following examples and comparative examples, and the contents of the invention will be described in more detail, but the present invention is not limited to these examples.

The following were used as solvents, reagents, and the like.
Dimethyl sulfoxide (DMSO); manufactured by Kanto Chemical Co., Inc.
Diethylene glycol monobutyl ether (BDG); manufactured by Kanto Chemical Co., Inc.
N-methylpyrrolidinone (NMP); manufactured by Kanto Chemical Co., Inc.
Benzyl alcohol (BnOH); manufactured by Kanto Chemical Co., Inc.
Gamma butyrolactone (GBL); manufactured by Kanto Chemical Co., Inc.
1-(2-Hydroxyethyl)-2-pyrrolidone (HEP); manufactured by Tokyo Chemical Industry Co., Ltd.
Tetrahydrofurfuryl alcohol (THFA); manufactured by Kanto Chemical Co., Inc.
Diethylene glycol monophenyl ether (PhDG); manufactured by Tokyo Chemical Industry Co., Ltd.
Diethylene glycol monobenzyl ether (BnDG); manufactured by Kanto Chemical Co., Inc.
Diethylene glycol monoethyl ether (EDG); manufactured by Kanto Chemical Co., Inc.
Glycerin; manufactured by Kanto Chemical Co., Inc.

Ethylene glycol (EG); manufactured by Kanto Chemical Co., Inc.
2-(2-Aminoethoxy) ethanol (AEE); manufactured by Kanto Chemical Co., Inc.
Monoethanolamine (MEA); manufactured by Kanto Chemical Co., Inc.
Diethanolamine (DEA); manufactured by Kanto Chemical Co., Inc.
5-Carboxybenzotriazole (5-CBTA); manufactured by Tokyo Chemical Industry Co., Ltd.

### Example 1 [Evaluation of Wettability]

In order to select a solvent effective for the ultrasonic process, the contact angle between copper and various solvents was evaluated. It can be presumed that the smaller the contact angle is, the higher the wettability to copper is and the higher the stripping performance is. In the stripping liquid, since copper is in various oxidation states, contact angles on three copper films of CuO, Cu₂O, and Cu were measured. In addition, the contact angle on an AlCu film was also measured assuming stripping on an aluminum film. Under the condition of 25° C., 1 μL of a solvent was dropped on a metal film, and the measurement was performed after 60 seconds elapsed.

TABLE 1

Contact angle (°)

| Solvent | CuO | Cu₂O | Cu | AlCu |
|---|---|---|---|---|
| DMSO | X | ◯ | ◯ | X |
| BDG | ◯ | X | X | X |
| NMP | X | ◯ | ◯ | X |
| BnOH | X | ◯ | X | X |
| GBL | X | ◯ | ◯ | ◯ |
| HEP | X | X | ◯ | X |
| THFA | X | ◯ | ◯ | X |
| PhDG | X | ◯ | X | X |
| BnDG | ◯ | ◯ | X | X |
| water | X | X | X | X |
| EDG | ◯ | ◯ | ◯ | ◯ |

### (Evaluation)

CuO: Contact angle is less than 20°=O, 20° or more=X
Cu₂O: Contact angle is less than 20°=O, 20° or more=X
Cu: Contact angle is less than 10°=O, 10° or more=X AlCu: Contact angle is less than 10°=O, 10° or more=X DMSO: dimethyl sulfoxide, BDG: diethylene glycol monobutyl ether, NMP: N-methylpyrrolidone, BnOH: benzyl alcohol, GBL: γ-butyrolactone, HEP: 1-(2-hydroxyethyl)-2-pyrrolidone, THFA: tetrahydrofurfuryl alcohol, PhDG: diethylene glycol monophenyl ether, BnOH: diethylene glycol monobenzyl ether, EDG: diethylene glycol monoethyl ether

The smaller the contact angle is, the higher the wettability on the metal film tends to be. EDG showed high wettability on all films. Thereafter, DMSO, NMP, and GBL showed relatively good wettability.

### Examples 2 to 9, and Comparative Examples 1 to 13

A stripping liquid was prepared using a solvent for which the wettability was evaluated in Example 1, and the stripping performance and metal damage were evaluated.

### [Evaluation of Stripping Performance]

For the evaluation of stripping performance, a Si substrate, in which an alkali development negative resist was applied onto a copper sputtered film and patterned, and then copper bumps were formed by copper plating, was used. The stripping treatment was performed by immersion in the stripping liquid at 65° C. for 10 minutes while ultrasonic waves at 110 W and 40 kHz were applied. After completion of the immersion in the stripping liquid, an overflow rinse with water was performed for 1 minute, and the substrate was dried by blowing nitrogen. The stripping performance was evaluated by observing the dried substrate with an optical microscope.

### (Evaluation)

O: Stripping performance is good (there is no resist residue).
Δ: Stripping performance is generally good (there is a slight resist residue).
X: Stripping performance is insufficient (there is a resist residue).
   [Evaluation of Cu damage]

For the evaluation of Cu damage, a Si substrate, on which a Cu sputtered film of 100 nm was formed, was used. The substrate was immersed in the stripping liquid at 65° C. for 10 minutes while ultrasonic waves at 110 W and 40 KHz were applied, and then an overflow rinse with water was performed for 1 minute, and the substrate was dried by blowing nitrogen. The copper film thickness of the dried substrate was analyzed using a wavelength dispersive fluorescent X-ray analyzer, and the etching rate (nm/min) was calculated.

### (Evaluation)

⊙: Cu etching rate is less than 1.0 nm/min.
O: Cu etching rate is 1.0 to less than 1.5 nm/min.
Δ: Cu etching rate is 1.5 to less than 5.0 nm/min.
X: Cu etching rate is 5.0 nm/min or more
   [Evaluation of AlCu damage]

For the evaluation of AlCu damage, a Si substrate, on which an AlCu sputtered film of 100 nm was formed, was used. The substrate was immersed in the stripping liquid at 65° C. for 10 minutes while ultrasonic waves at 110 W and 40 kHz were applied, and then an overflow rinse with water was performed for 1 minute, and the substrate was dried by blowing nitrogen. The AlCu film thickness of the dried substrate was analyzed using a wavelength dispersive fluorescent X-ray analyzer, and the etching rate (nm/min) was calculated.

### (Evaluation)

⊙: AlCu etching rate is less than 1.0 nm/min.
O: AlCu etching rate is 1.0 to less than 1.5 nm/min.
Δ: AlCu etching rate is 1.5 to less than 5.0 nm/min.
X: AlCu etching rate is 5.0 nm/min or more

TABLE 2

| | | | | | | | | Cu | AlCu |
|---|---|---|---|---|---|---|---|---|---|
| | Quaternary ammonium salt | | Solvent | | | | Evaluation | corrosion | corrosion |
| | Compound | Concentration | Compound | Concentration | Glycerin | Water | of stripping | prevention | prevention |
| Comparative | TMAH | 1.0% | DMSO | 90.0% | 6.0% | 3.0% | ◯ | Δ | ⊙ |
| Example 1 | | | | | | | | | |
| Comparative | TMAH | 1.0% | BDG | 90.0% | 6.0% | 3.0% | X | ⊙ | ⊙ |
| Example 2 | | | | | | | | | |
| Comparative | TMAH | 1.0% | NMP | 90.0% | 6.0% | 3.0% | ◯ | ⊙ | ⊙ |
| Example 3 | | | | | | | | | |
| Comparative | TMAH | 1.0% | BnOH | 90.0% | 6.0% | 3.0% | X | ⊙ | ⊙ |
| Example 4 | | | | | | | | | |
| Comparative | TMAH | 1.0% | GBL | 90.0% | 6.0% | 3.0% | Δ | ⊙ | ⊙ |
| Example 5 | | | | | | | | | |
| Comparative | TMAH | 1.0% | HEP | 90.0% | 6.0% | 3.0% | X | ⊙ | ⊙ |
| Example 6 | | | | | | | | | |
| Comparative | TMAH | 1.0% | THFA | 90.0% | 6.0% | 3.0% | X | ⊙ | ⊙ |
| Example 7 | | | | | | | | | |
| Comparative | TMAH | 1.0% | PhDG | 90.0% | 6.0% | 3.0% | X | ⊙ | ⊙ |
| Example 8 | | | | | | | | | |
| Comparative | TMAH | 1.0% | BnDG | 90.0% | 6.0% | 3.0% | X | ⊙ | ⊙ |
| Example 9 | | | | | | | | | |
| Comparative | TMAH | 1.0% | — | — | 6.0% | 93.0% | X | ◯ | X |
| Example 10 | | | | | | | | | |
| Example 2 | TMAH | 1.0% | EDG | 90.0% | 6.0% | 3.0% | ◯ | ⊙ | ⊙ |

TMAH: tetramethylammonium hydroxide

There was a tendency that good stripping performance is obtained with a chemical liquid composition in which a solvent having high Cu wettability is used. The EDG solvent composition (Example 2) having the best wettability exhibited high stripping performance equivalent to the NMP composition and good metal damage prevention performance, and exhibited sufficient performance as a substitute for NMP. The DMSO composition (Comparative Example 1) had high stripping performance, but showed large Cu damage.

TABLE 3

| | | | | | | | Evaluation | Cu | AlCu |
|---|---|---|---|---|---|---|---|---|---|
| | Quaternary ammonium salt | | | | | | of | corrosion | corrosion |
| | Compound | Concentration | EDG | EG | Glycerin | Water | stripping | prevention | prevention |
| Example 3 | TMAH | 2.0% | 72.5% | — | 15.0% | 10.0% | ◯ | ◯ | ◯ |
| Example 4 | TMAH | 1.0% | 85.0% | 5.0% | 6.0% | 3.0% | ◯ | ⊙ | ⊙ |
| Example 5 | TMAH | 2.0% | 68.0% | 5.0% | 15.0% | 10.0% | ◯ | ⊙ | ◯ |
| Comparative | TMAH | 1.0% | 96.0% | — | — | 3.0% | Δ | ⊙ | X |
| Example 11 | | | | | | | | | |
| Comparative | — | — | 91.0% | — | 6.0% | 3.0% | X | ⊙ | ⊙ |
| Example 12 | | | | | | | | | |
| Comparative | TMAH | 2.5% | 67.5% | — | 10.0% | 20.0% | X | ◯ | X |
| Example 13 | | | | | | | | | |

When the EDG solvent composition has a water concentration of about 10%, good stripping performance and metal damage prevention can be achieved (Example 3). By further adding ethylene glycol, it is possible to further prevent metal damage and improve stripping performance (Examples 4 and 5). A composition containing no TMAH or glycerin cannot prevent deterioration of stripping performance and metal damage, and therefore these are essential components (Comparative Examples 11 and 12). When the water concentration is set to 20% or more, stripping performance is deteriorated and AlCu corrosion occurs, and therefore the water concentration is desirably less than 20% (Comparative Example 13).

TABLE 4

| | | | | | | | | | | Cu | AlCu |
|---|---|---|---|---|---|---|---|---|---|---|---|
| | Quaternary ammonium salt | | | | Amine | | | | Evaluation | corrosion | corrosion |
| | Compound | Concentration | EDG | EG | Compound | Concentration | Glycerin | Water | of stripping | prevention | prevention |
| Example | TMAH | 1.5% | 81.0% | 5.0% | AEE | 2% | 6.0% | 4.5% | ◯ | ◯ | ⊙ |
| 6 | | | | | | | | | | | |
| Example | TMAH | 2.0% | 53.0% | 5.0% | AEE | 15% | 15.0% | 10.0% | ◯ | ⊙ | ⊙ |
| 7 | | | | | | | | | | | |
| Example | TMAH | 2.5% | 50.5% | 5.0% | MEA | 14.0% | 15.0% | 13.0% | ◯ | ◯ | ◯ |
| 8 | | | | | | | | | | | |
| Example | TMAH | 2.0% | 53.0% | 5.0% | DEA | 15% | 15.0% | 10.0% | ◯ | ⊙ | ⊙ |
| 9 | | | | | | | | | | | |

AEE: 2-(2-aminoethoxy)ethanol,
MEA: 2-aminoethanol,
DEA: diethanolamine

Even with the chemical composition to which an amine was added, good stripping performance and metal damage prevention performance were obtained (Examples 6 to 9). In the amine-containing composition, the alkali component increases, and therefore improvement of the stripping performance and extension of the liquid life can be expected.

Examples 10 and 11, and Comparative Examples 14 to 16

The oxidation amount of copper during the stripping liquid process was evaluated.

### [Evaluation of Cu Oxidation Prevention]

The oxidization amount of Cu during the stripping process was evaluated using a Si substrate on which a Cu sputtered film of 100 nm was formed. The substrate was immersed in the stripping liquid at 65° C. for 10 minutes while ultrasonic waves at 110 W and 40 kHz were applied, and then an overflow rinse with water was performed for 30 minutes, and the substrate was dried by blowing nitrogen. The atom number ratio of oxygen atoms to copper atoms (number of oxygen atoms/number of copper atoms) of the dried Cu film was determined using X-ray photoelectron spectroscopy (XPS). By calculating the atom number ratio of the Cu film before the stripping treatment and the increase rate of the atom number ratio after the stripping treatment, the increase amount of copper oxide was used as a guide.

### [Evaluation of Stripping Performance]

Resist stripping performance was evaluated in the same manner as in Examples 2 to 9 and Comparative Examples 1 to 13.

TABLE 5

| | | | | | | | | | | | | | Resid- |
|---|---|---|---|---|---|---|---|---|---|---|---|---|---|
| | | | | | | | | | | | | | ual |
| | | | | | | | | | | | | | organic |
| | | | | | | | | | | | | In- | sub- |
| | | | | | | | | | | | Eval- | crease | stance |
| | Quaternary ammonium salt | | Solvent | | Antioxidant | | Amine | | | | uation | rate of | on |
| | Com- | Concen- | Com- | Concen- | Com- | Concen- | Com- | Concen- | Glyc- | | of | copper | Cu |
| | pound | tration | pound | tration | pound | tration | pound | tration | erin | Water | stripping | oxide | surface |
| Compar- | TMAH | 1.0% | DMSO | 90.0% | — | — | — | — | 6.0% | 3.0% | ◯ | +9.5% | — |
| ative | | | | | | | | | | | | | |
| Example | | | | | | | | | | | | | |
| 14 | | | | | | | | | | | | | |
| Example | TMAH | 1.0% | EDG | 90.0% | — | — | — | — | 6.0% | 3.0% | ◯ | +5.0% | — |
| 10 | | | | | | | | | | | | | |
| Example | TMAH | 1.0% | EDG | 88.8% | 5-CBTA | 0.20% | DEA | 1.0% | 6.0% | 3.0% | ◯ | +1.8% | Almost |
| 11 | | | | | | | | | | | | | none |

In the composition using a DMSO solvent in place of an EDG solvent (Comparative Example 14), the production of copper oxide is greatly promoted, and there is a possibility that device defects will occur when the DMSO solvent is used in an actual process. In the case of the composition using the EDG solvent (Example 10), the production of copper oxide was reduced to about half that in the case of the DMSO solvent composition (Comparative Example 14).

By adding an antioxidant, production of copper oxide could be further prevented (Example 11). In addition, when a large amount of an organic substance remained on the Cu surface, poor device characteristics may be caused, but when CBTA was used as an antioxidant, an organic substance derived from the antioxidant did not remain on the Cu surface after completion of rinsing.

### Examples 12 and 13

With respect to the stripping liquid compositions used in Examples 2 and 4, the stripping performance and metal damage were evaluated under the condition that no ultrasonic waves were applied.

### [Evaluation of Stripping Performance]

For the evaluation of stripping performance, a Si substrate, in which an alkali development negative resist was applied onto a copper sputtered film and patterned, and then copper bumps were formed by copper plating, was used. The stripping treatment was performed by immersion in the stripping liquid at 65° C. for 30 minutes with stirring at 300 rpm. After completion of the immersion in the stripping liquid, an overflow rinse with water was performed for 1 minute, and the substrate was dried by blowing nitrogen. The stripping performance was evaluated by observing the dried substrate with an optical microscope.

### (Evaluation)

O: Stripping performance is good (there is no resist residue).
Δ: Stripping performance is generally good (there is a slight resist residue).
X: Stripping performance is insufficient (there is a resist residue).

### [Evaluation of Cu Damage]

For the evaluation of Cu damage, a Si substrate, on which a Cu sputtered film of 100 nm was formed, was used. The substrate was immersed in the stripping liquid at 65° C. for 10 minutes with stirring at 300 rpm, and then an overflow rinse with water was performed for 1 minute, and the substrate was dried by blowing nitrogen. The copper film thickness of the dried substrate was analyzed using a wavelength dispersive fluorescent X-ray analyzer, and the etching rate (nm/min) was calculated.

### (Evaluation)

⊙: Cu etching rate is less than 1.0 nm/min.
O: Cu etching rate is 1.0 to less than 1.5 nm/min.
Δ: Cu etching rate is 1.5 to less than 5.0 nm/min.
X: Cu etching rate is 5.0 nm/min or more

### [Evaluation of AlCu Damage]

For the evaluation of AlCu damage, a Si substrate, on which an AlCu sputtered film of 100 nm was formed, was used. The substrate was immersed in the stripping liquid at 65° C. for 10 minutes with stirring at 300 rpm, and then an overflow rinse with water was performed for 1 minute, and the substrate was dried by blowing nitrogen. The AlCu film thickness of the dried substrate was analyzed using a wavelength dispersive fluorescent X-ray analyzer, and the etching rate (nm/min) was calculated.

### (Evaluation)

⊙: AlCu etching rate is less than 1.0 nm/min.
O: AlCu etching rate is 1.0 to less than 1.5 nm/min.
Δ: AlCu etching rate is 1.5 to less than 5.0 nm/min.
X: AlCu etching rate is 5.0 nm/min or more

TABLE 6

| | | | | | | | Evaluation | | AlCu |
|---|---|---|---|---|---|---|---|---|---|
| | Quaternary ammonium salt | | | | | | of | Cu etching | etching |
| | Compound | Concentration | EDG | EG | Glycerin | Water | stripping | rate | rate |
| Example | TMAH | 1.0% | 90.0% | — | 6.0% | 3.0% | ◯ | ⊙ | ⊙ |
| 12 | | | | | | | | | |
| Example | TMAH | 1.0% | 85.0% | 5.0% | 6.0% | 3.0% | ◯ | ⊙ | ⊙ |
| 13 | | | | | | | | | |

Although it takes more time to complete stripping than when ultrasonic waves are applied, stripping is possible while metal damage is prevented. Therefore, the stripping composition of the present invention exhibits excellent stripping performance while metal corrosion is prevented and excessive metal oxidation during the stripping process is prevented even when there is no device for emitting ultrasonic waves.

1. A photoresist stripping composition, the composition comprising a quaternary ammonium hydroxide (A), diethylene glycol monoethyl ether (B), glycerin (C), and water (D), wherein a content of (A) is 0.5 to 5 mass % with respect to a total mass of the composition, a content of (B) is 50 to 95 mass % with respect to the total mass of the composition, a content of (C) is 0.5 to 20 mass % with respect to the total mass of the composition, and a content of (D) is less than 20 mass % with respect to the total mass of the composition.

2. The composition of claim 1, wherein the composition does not contain hydroxylamine or a hydroxylamine salt.

3. The composition of claim 1, wherein the content of water (D) is 5 mass % or less with respect to the total mass of the composition.

4. The composition of claim 1, wherein the composition further comprises ethylene glycol (E), a content of which is 1 to 10 mass % with respect to the total mass of the composition.

5. The composition of claim 1, wherein the composition further comprises an alkanolamine (F), a content of which is 1 to 20 mass % with respect to the total mass of the composition.

6. The composition of claim 1, wherein the alkanolamine (F) is monoethanolamine, diethanolamine, or 2-(2-aminoethoxy) ethanol.

7. The composition of claim 1, wherein the composition further comprises (G) at least one selected from a group consisting of 4-carboxybenzotriazole and 5-carboxybenzotriazole, wherein a total content of (G) is 0.05 to 1.00 mass % with respect to the total mass of the composition.

8. The composition of claim 1, wherein the quaternary ammonium hydroxide (A) is one or more selected from a group consisting of tetramethylammonium hydroxide, tetraethylammonium hydroxide, choline hydroxide, and ethyltrimethylammonium hydroxide.

9. The composition of claim 1, wherein the composition does not contain dimethyl sulfoxide or N-methylpyrrolidone.

10. The composition of claim 1, wherein the composition does not contain sodium hydroxide or potassium hydroxide.

11. The composition of claim 1, wherein the composition does not contain a triazine compound.

12. A photoresist stripping method, comprising bringing a photoresist applied onto a substrate having metal wiring or a semiconductor substrate containing a photoresist residue into contact with the composition of claim 1 to remove the photoresist.
